(19) United States
(12) Patent Application Publication
(10) Pub. No.: US 2025/0174491 A1
(43) Pub. Date: May 29, 2025

(54) Semiconductor layout pattern and semiconductor stack structure suitable for power amplifier

(71) Applicant: United Microelectronics Corp., Hsin-Chu City (TW)

(72) Inventors: Wei Lun Oo, Singapore (SG); Su Xing, Singapore (SG); Jinyu Liao, Singapore (SG)

(73) Assignee: United Microelectronics Corp., Hsin-chu City (TW)

(21) Appl. No.: 18/534,741

(22) Filed: Dec. 11, 2023

(30) Foreign Application Priority Data
Nov. 27, 2023 (TW) 112145769

(51) Int. Cl. H01L 21/768; H01L 21/8234; H01L 27/02; H01L 29/06; H01L 29/08; H01L 29/423

(52) U.S. Cl. CPC H01L 21/76816; H10D 62/127; H10D 62/154; H10D 62/158; H10D 64/519; H10D 84/0149; H10D 84/038; H10D 89/10

(57) ABSTRACT

The invention provides a semiconductor layout pattern, which comprises a substrate, a plurality of gate metal frames arranged on the substrate, a plurality of source/drain patterns and a plurality of gate patterns extending along an X direction and located in each gate metal frame, and the source/drain patterns and the plurality of gate patterns are alternately arranged along a Y direction, wherein any two adjacent gate metal frames are partially overlapped with each other, and the overlapping part of the two gate metal frames is defined as an overlapping line.

### BACKGROUND OF THE INVENTION

### 1. Field of the Invention

The invention relates to the field of semiconductors, in particular to a semiconductor layout pattern and a semiconductor stacked structure suitable for power amplifiers.

### 2. Description of the Prior Art

Power amplifier is an important component in RF power transmission. Its main function is to amplify and output signals. It is usually designed at the front end of antenna radiator, and it is also the most power-consuming component in the whole RF front-end circuit.

Power amplifiers are mainly used in electronic products or devices that need bandwidth, such as mobile phones, tablet computers, WiMAX, Wi-Fi, bluetooth, RFID readers, satellite communications and other network communication products.

Today's power amplifier still has room for improvement, for example, its layout pattern occupies a large area, which is not conducive to the miniaturization of products.

### SUMMARY OF THE INVENTION

The invention provides a semiconductor layout pattern, which comprises a substrate, a plurality of gate metal frames are arranged on the substrate, each gate metal frame comprises a plurality of source/drain patterns and a plurality of gate patterns extending along an X direction, and the source/drain patterns and the plurality of gate patterns are alternately arranged along a Y direction, any two adjacent gate metal frames have a part overlapping with each other, and the overlapping part of the two gate metal frames is defined as an overlapping line.

The invention provides a semiconductor stacking structure, which comprises a substrate, a first chip and a second chip are stacked on the substrate, the first chip and the second chip respectively comprise a first power amplifier and a second power amplifier, and the first power amplifier and the second power amplifier respectively comprise a source terminal, a drain terminal and a gate terminal, the drain terminal of the first power amplifier is electrically connected with the source terminal of the second power amplifier, and the first power amplifier and the second power amplifier are stacked to form a cascade power amplifier.

The invention is characterized by providing a semiconductor layout pattern suitable for composing a power amplifier, and a power amplifier formed by stacking the semiconductor layout patterns mentioned above. Each power amplifier layout pattern comprises a plurality of gate metal frames, and each gate metal frame is arranged next to each other, that is to say, there is no gap between the gate metal frames, and the subsequent contact structures or wires partially overlap the gate metal frames. In this way, the gate metal frames can be arranged more closely with each other, and the area of the overall semiconductor layout pattern can be reduced. According to the experimental results of the applicant, when the improved semiconductor layout pattern provided by the invention is applied to a power amplifier, the efficiency of the power amplifier can also be effectively improved. Besides, the invention also provides a cascade power amplifier structure formed by stacking two semiconductor layout patterns, and the cascade power amplifier formed by the invention has better efficiency and smaller area.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

In order to make the following easier to understand, readers can refer to the drawings and their detailed descriptions at the same time when reading the present invention. Through the specific embodiments in the present specification and referring to the corresponding drawings, the specific embodiments of the present invention will be explained in detail, and the working principle of the specific embodiments of the present invention will be expounded. In addition, for the sake of clarity, the features in the drawings may not be drawn to the actual scale, so the dimensions of some features in some drawings may be deliberately enlarged or reduced.

FIG. 1 shows a schematic top view of a semiconductor unit pattern according to an embodiment of the present invention.

FIG. 2 shows a top view of a layout pattern of a power amplifier cell according to an embodiment of the present invention.

FIG. 3 shows a top view of a layout pattern after forming circuit layers and contact structures according to the structure shown in FIG. 2.

FIG. 4 shows a top view of a layout pattern of a power amplifier cell according to another embodiment of the present invention.

FIG. 5 shows a top view of a layout pattern after forming circuit layers and contact structures according to the structure shown in FIG. 4.

FIG. 6 shows a schematic circuit diagram of a cascade power amplifier.

FIG. 7 is a schematic diagram showing the relative positions of the layout patterns of two power amplifiers stacked on each other.

FIG. 8 is a schematic cross-sectional view of two power amplifiers stacked on each other.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

Although the present invention uses the terms first, second, third, etc. to describe elements, components, regions, layers, and/or sections, it should be understood that such elements, components, regions, layers, and/or sections should not be limited by such terms. These terms are only used to distinguish one element, component, region, layer and/or block from another element, component, region, layer and/or block. They do not imply or represent any previous ordinal number of the element, nor do they represent the arrangement order of one element and another element, or the order of manufacturing methods. Therefore, the first element, component, region, layer or block discussed below can also be referred to as the second element, component, region, layer or block without departing from the specific embodiments of the present invention.

The term “about” or “substantially” mentioned in the present invention usually means within 20% of a given value or range, such as within 10%, or within 5%, or within 3%, or within 2%, or within 1%, or within 0.5%. It should be noted that the quantity provided in the specification is approximate, that is, the meaning of “about” or “substantially” can still be implied without specifying “about” or “substantially”.

The terms “coupling” and “electrical connection” mentioned in the present invention include any direct and indirect means of electrical connection. For example, if the first component is described as being coupled to the second component, it means that the first component can be directly electrically connected to the second component, or indirectly electrically connected to the second component through other devices or connecting means.

Although the invention of the present invention is described below by specific embodiments, the inventive principles of the present invention can also be applied to other embodiments. In addition, in order not to obscure the spirit of the present invention, specific details are omitted, and the omitted details are within the knowledge of those with ordinary knowledge in the technical field.

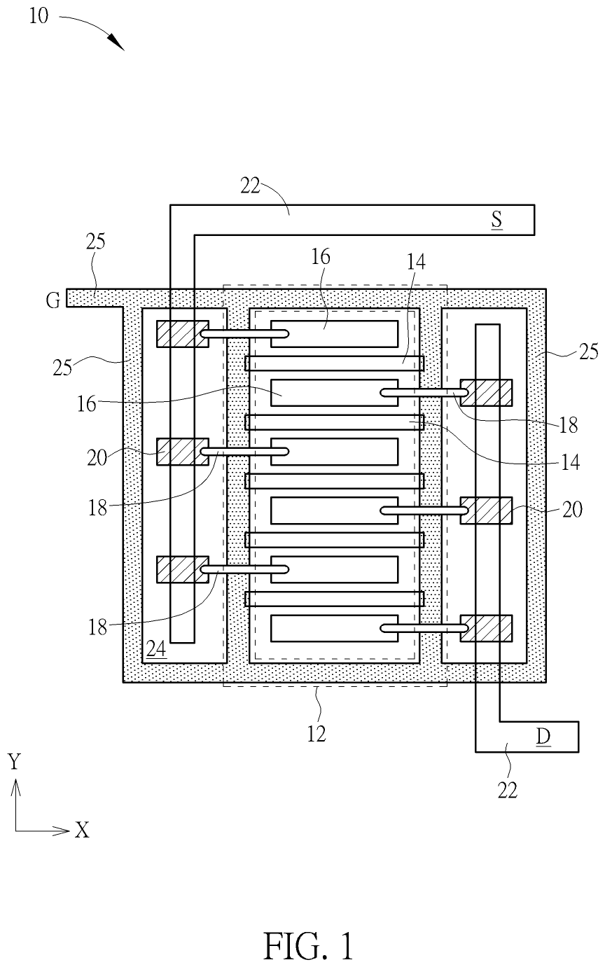

Please refer to FIG. 1, which shows a schematic diagram of a semiconductor unit pattern according to an embodiment of the present invention. As shown in FIG. 1, a semiconductor unit pattern 10 is provided, which comprises a gate metal frame 12, and a plurality of gate patterns 14 and a plurality of source/drain patterns 16 which are parallel to each other are arranged in the gate metal frame 12, the plurality of gate patterns 14 and the plurality of source/drain patterns 16 extend along the X direction, for example, and the plurality of gate patterns 14 and the plurality of source/drain patterns 16 are alternately arranged along the Y direction. In other words, when viewed along the Y direction, patterns in the gate metal frame 12 are arranged in the order of source/drain pattern 16, gate pattern 14, source/drain pattern 16, gate pattern 14, source/drain pattern 16 . . . , and so on. Each gate pattern 14 is electrically connected to the gate metal frame 12, which may be electrically connected to the gate metal frame 12 through a contact structure (not shown). The source/drain pattern 16 is located on the upper side (+Y direction) and lower side (−Y direction) of the gate pattern 14 in the gate metal frame 12, and the source/drain pattern 16 will be electrically connected with a source terminal S and a drain terminal D in the following period. In the process, a plurality of parallel gate patterns 14 and a plurality of source/drain patterns 16 may be formed on a substrate (not shown) first, and then a gate metal frame 12 is formed to surround and electrically connect the gate patterns 14, but the present invention is not limited to this.

In addition, the semiconductor unit pattern 10 in FIG. 1 additionally includes a conductive pattern 25 connected to the gate metal frame 12. The conductive pattern 25 and the gate metal frame 12 may be integrally formed, that is, they may be formed at the same time and comprise the same material. The function of the conductive pattern 25 is to electrically connect the gate metal frame 12 to a gate terminal G. In this embodiment, the gate metal frame 12 refers to a portion (for example, a rectangular frame) surrounding and adjacent to a plurality of gate patterns 14 and a plurality of source/drain patterns 16, while the rest of the portion directly connected with the gate metal frame 12 is defined as the conductive pattern 25 because it does not surround a plurality of gate patterns 14 and a plurality of source/drain patterns 16. In addition, the conductive pattern 25 defines a region 24, which is used to accommodate the contact structure (not shown) formed later, and the details will be explained in the following paragraphs.

The semiconductor unit pattern 10 further comprises a plurality of conductive lines 18, a plurality of source/drain contact structures 20 and a plurality of source/drain circuit layers 22, the conductive lines 18 connect each source/drain pattern 16 with the source/drain contact structures 20, and the source/drain circuit layers 22 connect the source/drain contact structures 20 to a source terminal S or a drain terminal D. Among them, the materials of the conductive line 18, the source/drain contact structure 20 and the source/drain circuit layer 22 may include metals with good conductivity such as tungsten, cobalt, copper, aluminum, gold, etc., but are not limited thereto. In addition, it is worth noting that the source/drain contact structure 20 is accommodated in the two side regions 24 of the gate metal frame 12, where the region 24 is a blank region located on both sides of the gate metal frame 12, the gate pattern 14 or the source/drain pattern 16 is not formed in the region 24, and the function of the region 24 is to accommodate the source/drain contact structure 20. The source/drain circuit layer 22 is connected to a plurality of source/drain contact structures 20 located in the region 24 and connected to the source terminal S or the drain terminal D, that is, the source terminal S or the drain terminal D is electrically connected to each source/drain pattern 16 through the paths of the source/drain circuit layer 22, the source/drain contact structures 20 and the conductive lines 18.

In addition, the gate patterns 14 are connected to each other through the gate metal frame 12 and electrically connected to a gate terminal G through the gate metal frame 12. The above-mentioned gate metal frame 12 and gate pattern 14 can be separately formed in different steps or integrally formed at the same time, which are within the scope of the present invention.

The semiconductor unit pattern 10 shown in FIG. 1 can be regarded as the smallest unit of the circuit layout pattern of a power amplifier. By inputting appropriate signals at each terminal (gate terminal G, source terminal S and drain terminal D), the amplified signal can be output at the other terminal. Alternatively, the semiconductor unit pattern 10 shown in FIG. 1 can be combined with other circuits to form a power amplifier with higher efficiency, or combined into other types of power amplifiers.

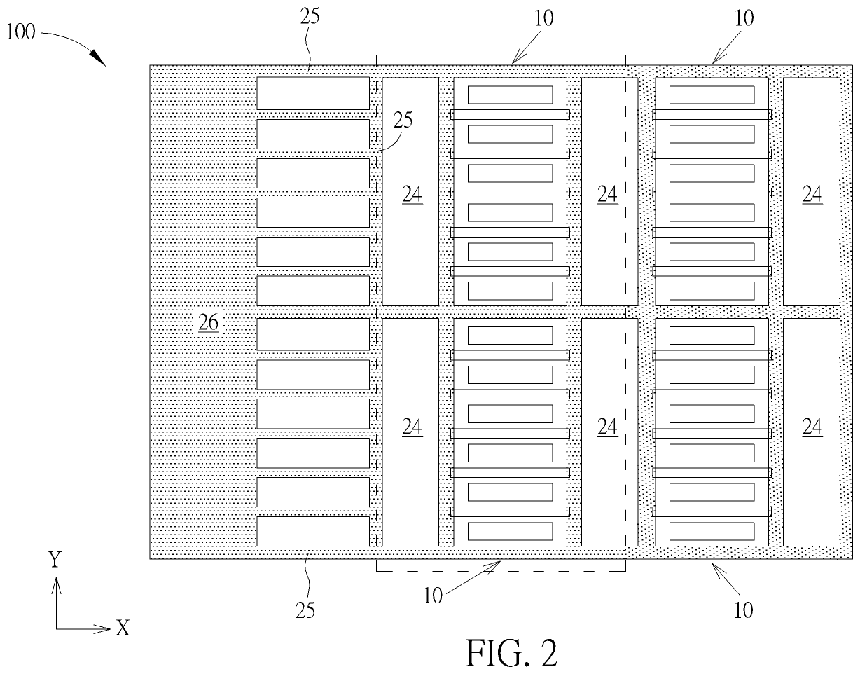

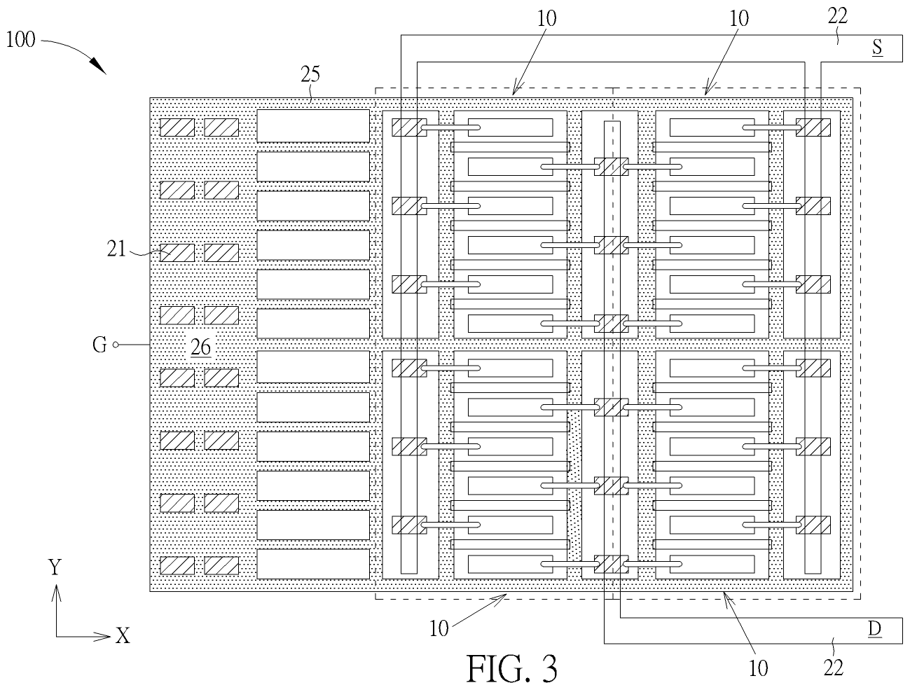

For example, the semiconductor unit patterns 10 in FIG. 1 can be arranged in an array to form patterns as shown in FIGS. 2 and 3. FIG. 2 shows a top view of the layout pattern of a power amplifier cell according to an embodiment of the present invention, and FIG. 3 shows a top view of the layout pattern after the circuit layers and contact structures are formed according to the structure shown in FIG. 2. As shown in FIG. 2 and FIG. 3, a power amplifier pattern 100 can be composed of a plurality of the above-mentioned semiconductor unit patterns 10, and more specifically, the above-mentioned semiconductor unit patterns 10 can be arranged in an array, in the equivalent circuit, the plurality of semiconductor unit patterns 10 are regarded as being connected in parallel with each other, so that a power amplifier with higher efficiency can be formed.

In this embodiment, each gate metal frame 12 is connected to a common gate pad 26 through the conductive patterns 25. As mentioned above, the gate metal frame 12 refers to a metal frame pattern (preferably a rectangular frame pattern) surrounding a plurality of source/drain patterns 16 and gate patterns 14, and adjacent to the source/drain patterns 16. The common gate pad 26 is formed next to the array in which a plurality of semiconductor unit patterns 10 are arranged, and the gate contact structure 21 can be formed on the common gate pad 26 and electrically connected to the gate terminal G. As for the conductive pattern 25 mentioned here, it refers to the X-direction metal line electrically connecting the gate metal frame 12 and the common gate pad 26 in FIG. 2, and the metal line surrounding the above-mentioned region 24 is also a part of the conductive pattern 25. That is, in FIG. 2 or FIG. 3, the gate metal frame 12, the common gate pad 26 and the conductive pattern 25 can be integrally formed, that is, they are made of the same material and formed at the same time. The conductive pattern 25 is other conductive patterns except the gate metal frame 12 and the common gate pad 26.

It should be noted that in the embodiments shown in FIGS. 2 and 3, the regions 24 are included on both sides of the gate metal frames 12, so when a plurality of semiconductor unit patterns 10 are arranged in an array, the regions 24 will be repeatedly arranged on both sides of each gate metal frame 12. When more gate metal frames 12 are arranged, the total area occupied by regions 24 will be larger, which is not conducive to miniaturization of products.

In the above inventive concept, the region 24 is used to accommodate the source/drain contact structure 20, so the source/drain contact structure 20 will not overlap the source/drain pattern 16 or the gate metal frame 12 when viewed from the top. However, since the source/drain contact structure 20, the source/drain pattern 16 and the gate metal frame 12 are formed in different layers (i.e., the source/drain pattern 16 is formed first, then the gate metal frame 12 is formed, and then the conductive lines 18 and the source/drain contact structure 20 are formed in different layers), in other embodiments of the present invention, the gate metal frame 12 may be closely arranged and the region 24 may be omitted.

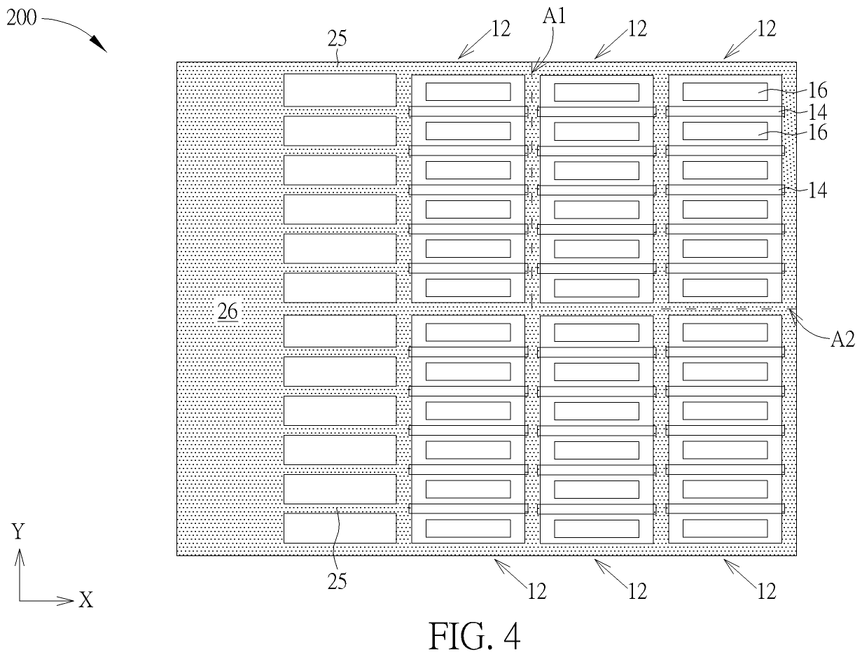

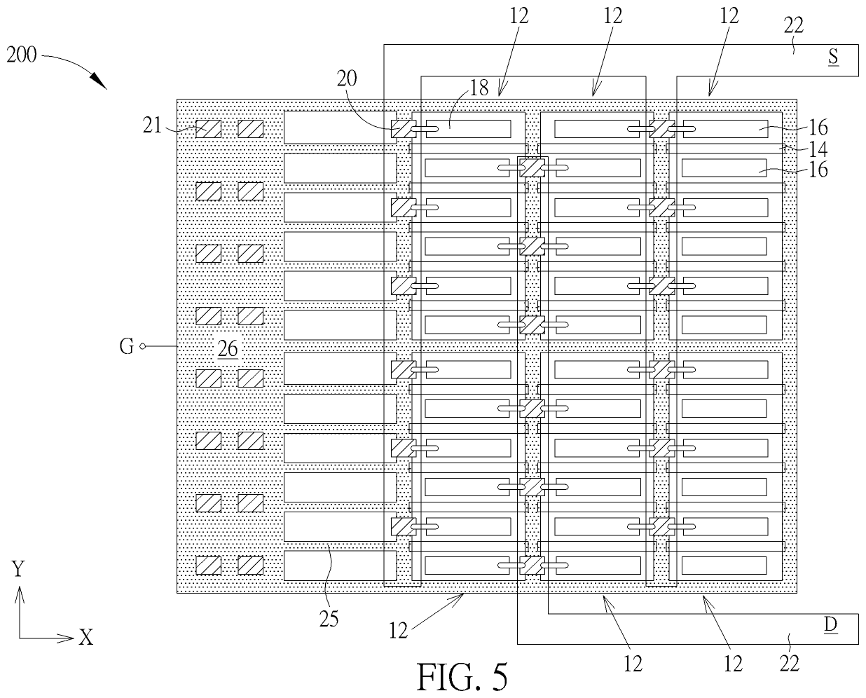

For more details, please refer to FIGS. 4 and 5. FIG. 4 shows a top view of the layout pattern of a power amplifier cell according to another embodiment of the present invention, and FIG. 5 shows a top view of the layout pattern after the circuit layers and contact structures are formed according to the structure shown in FIG. 4. In this embodiment, a power amplifier pattern 200 is provided, in which most elements included in the power amplifier pattern 200 are the same as those in the above-mentioned embodiment, and detailed descriptions are not repeated. However, in this embodiment, the gate metal frames 12 are closely arranged with each other, that is, the regions 24 are not included between the gate metal frames 12. More specifically, there may be some overlap between the two gate metal frames 12, and the overlap is defined as an overlapping line. If two gate metal frames 12 are adjacent to each other in the X direction, the overlapping line A1 is arranged in the Y direction. On the other hand, if two gate metal frames 12 are adjacent to each other in the Y direction, the overlapping line A2 is arranged in the X direction.

In FIG. 4 and FIG. 5, for the sake of simplicity, some elements are not labeled in detail, but the detailed structure can be referred to in FIG. 1 together, in which the elements located in the gate metal frame 12 are the same.

In this embodiment, the gate metal frame 12 is formed in a dielectric layer (not shown), and the conductive line 18 and the source/drain contact structure 20 are formed in another dielectric layer (not shown) above. Therefore, even if the source/drain contact structure 20 overlaps the gate metal frame 12 from the top view, actually the source/drain contact structure 20 is not electrically connected with the gate metal frame 12, but is electrically connected with the source/drain pattern 16 through the conductive lines 18. Compared with the above-mentioned embodiments, this embodiment saves the space of region 24, so the total area of components can be greatly reduced and the component density can be improved. According to the applicant's experimental results, under the condition of accommodating the same number of components, the total area of components in this embodiment is reduced by about 55% compared with the embodiments shown in the above-mentioned FIGS. 2 and 3, thus greatly reducing the area occupied by components.

In addition, according to the applicant's experimental results, the efficiency of the power amplifier formed by the embodiment shown in FIG. 5 is also better than that of the embodiment shown in FIG. 3. According to the experimental results, at the input frequency of 28 GHz, its gain is increased by about 2 dB (from the original 6 dB to about 8 dB).

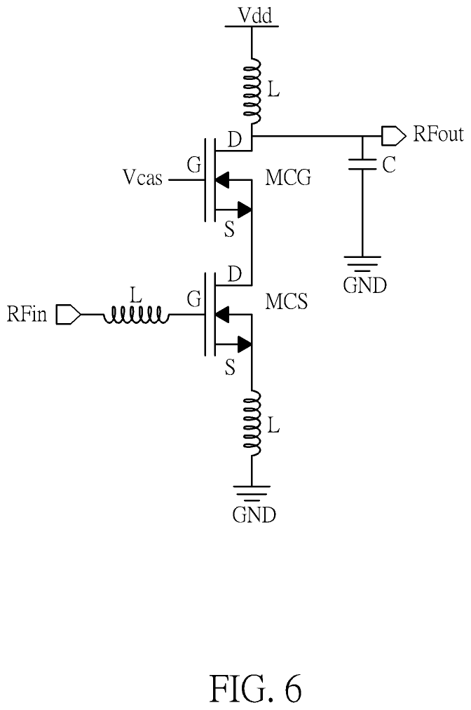

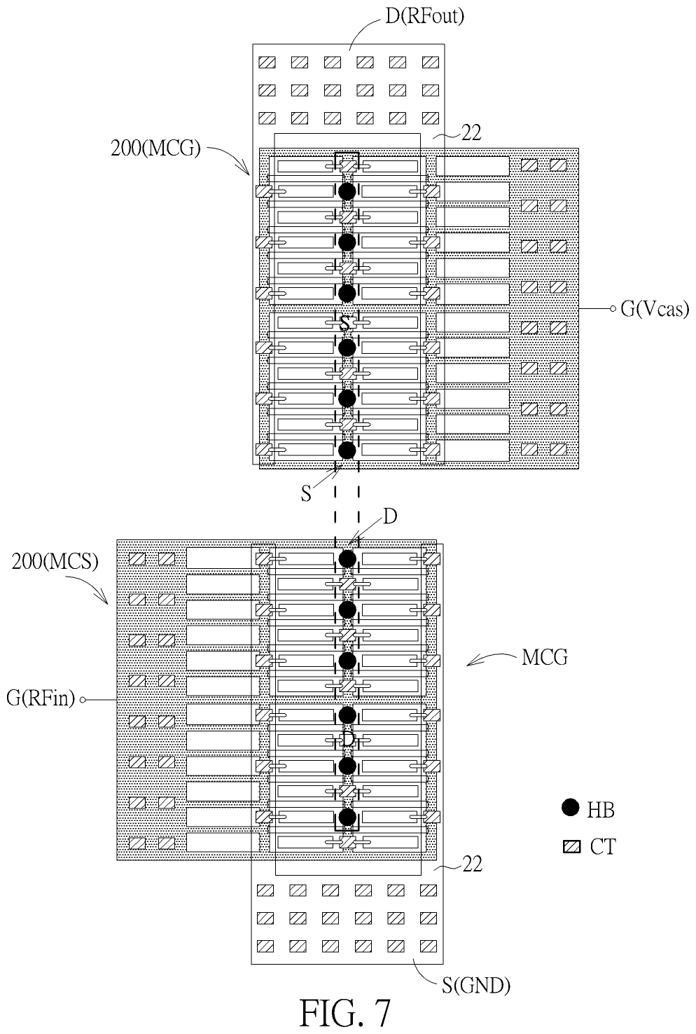

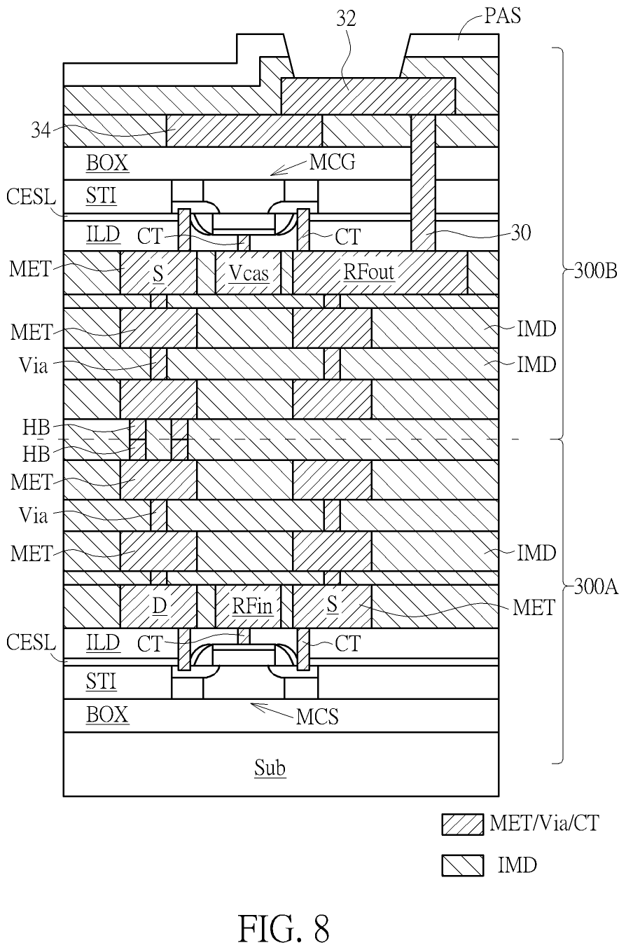

In addition to using the layout pattern shown in FIG. 3 or FIG. 5 as the power amplifier, the present invention can also stack a plurality of layout patterns to form other kinds of power amplifiers. Please refer to FIG. 6, FIG. 7 and FIG. 8. FIG. 6 shows a schematic circuit diagram of a cascade power amplifier, FIG. 7 shows a schematic diagram of the relative positions of the layout patterns of two power amplifiers stacked with each other, and FIG. 8 shows a schematic diagram of the cross-sectional structure of two power amplifiers stacked with each other. As shown in FIG. 6, a cascade power amplifier comprises a first power amplifier MCS and a second power amplifier MCG, the first power amplifier MCS is a common source amplifier circuit, its gate terminal G is connected to an input signal RFin, and its source terminal S is connected to the ground potential GND. The second power amplifier MCG is a common gate amplifier circuit, the gate terminal G of which is connected to a voltage source Vcas, the drain terminal D is connected to the output signal RFout, and the drain terminal D of the first power amplifier MCS is connected to the source terminal S of the second power amplifier MCG. In addition, the circuit diagram in FIG. 6 also includes some inductors L, capacitors C and voltage source Vdd connected to the circuit. These contents belong to the conventional circuit technology of cascade power amplifiers, and do not belong to the key features of the present invention, so they are not repeated here.

The power amplifier 200 shown in FIG. 5 of the present invention can form the first power amplifier MCS or the second power amplifier MCG in the circuit diagram of FIG. 6 by connecting different signal sources or elements at the gate terminal G, the source terminal S and the drain terminal D. For example, as shown in FIG. 7, two power amplifiers 200 shown in FIG. 5 are respectively connected with different signals at the gate terminal G, the source terminal S and the drain terminal D to form a first power amplifier MCS and a second power amplifier MCG shown in FIGS. 6 and 7. For example, the gate terminal G of the first power amplifier MCS is connected to the input signal RFin, and the source terminal S of the first power amplifier MCS is connected to the ground potential GND. The gate terminal G of the second power amplifier MCG is connected to a voltage source Vcas, and the drain terminal D is connected to the output signal RFout, and then the drain terminal D of the first power amplifier MCS is connected to the source terminal S of the second power amplifier MCG. Among them, the drain terminal D of the first power amplifier MCS and the source terminal S of the second power amplifier MCG can be connected to each other by a hybrid bond (HB), that is, a hybrid bond contact can be formed on the circuit layer on its surface, and then the two hybrid bond contacts are directly touched and bonded.

In addition, in FIG. 7, in order to clearly indicate the respective connection signal sources of the two power amplifiers located above and below (namely, the first power amplifier MCS and the second power amplifier MCG), the two power amplifiers are drawn below and above in FIG. 7, but in fact, the two power amplifiers should be stacked on each other in the vertical direction, so from the top view, the two power amplifiers should actually overlap each other at the hybrid bond HB. In addition, FIG. 7 shows a partial contact structure CT, which is used to connect the power amplifier to a signal source (such as RFin, RFout or grounding).

Other components of the power amplifier in FIG. 7 can be refer to components shown in FIGS. 4 and 5, and some components are not labeled for simplicity.

FIG. 8 shows the schematic cross-sectional structure of two power amplifiers stacked on each other. Please refer to FIGS. 7 and 8 together. The first power amplifier MCS and the second power amplifier MCG can be formed on different chips respectively, and then the two chips can be bonded by hybrid bond. As shown in FIG. 8, the first chip 300A includes a substrate Sub, a buried oxide BOX is stacked on the substrate Sub, and a first power amplifier MCS is formed on the buried oxide BOX. The first power amplifier MCS is surrounded by shallow trench isolation STI and covered with a contact etch stop layer CESL and an interlayer dielectric ILD. Then, a contact structure CT is connected above the first power amplifier MCS, and a multi-layer metal layers MET or a plurality of contact plugs Via are formed above it, which are located in the multi-layer dielectric layer IMD, and a hybrid bond HB is formed on the topmost metal layer MET. Similarly, the second chip 300B includes a buried oxide layer BOX, a second power amplifier MCG, a contact etch stop layer CESL, an interlayer dielectric layer ILD, a plurality of contact structures CT, a plurality of metal layers MET, a plurality of contact plugs Via, and hybrid bonds HB. In addition, the back surface of the second chip 300B (i.e., the upward direction in FIG. 8) also includes a back contact post 30, which is electrically connected to a re-distribution layer (RDL) 32. The re-distribution layer 32 is located in an oxide layer PEOX and partially exposed by the oxide layer PEOX, and further includes a passivation layer PAS covering the oxide layer PEOX. In addition, in some embodiments, a heat sink 34 can be formed on the back (i.e., above) of the second power amplifier MCG to improve the heat diffusion efficiency and prevent the components from overheating.

The above-mentioned substrate Sub is made of silicon, the buried oxide layer BOX and the oxide layer PEOX are made of silicon oxide, the shallow trench isolation STI, the contact etch stop layer CESL, the interlayer dielectric layer ILD, the inter-metal dielectric layer IMD and the passivation layer pas are made of silicon, silicon nitride or silicon oxynitride, while the contact structure CT, the metal layer MET, the contact plugs Via, the hybrid bond HB, the back contact post 30 and the re-distribution layer 32 are made of metal.

In order to clearly indicate the connection relationship between the first power amplifier MCS and the second power amplifier MCG and other signal sources, such as the source terminal S, the drain terminal D, the input signal RFin, the output signal RFout, the voltage source Vcas, etc. are indicated in some metal layers MET in FIG. 8. Therefore, it can be seen from FIG. 8 that the drain terminal D of the first power amplifier MCS and the source terminal S of the second power amplifier MCG can be connected to each other by a hybrid bond HB, and form a cascade power amplifier as shown in FIG. 6.

Based on the above description and drawings, the present invention provides a semiconductor layout pattern 200, which comprises a substrate Sub, and a plurality of gate metal frames 12 are arranged on the substrate Sub, wherein each gate metal frame 12 comprises a plurality of source/drain patterns 16 and a plurality of gate patterns 14 extending along an X direction, and the source/drain patterns 16 and the plurality of gate patterns 14 are alternately arranged along a Y direction, wherein any two adjacent gate metal frames 12 have a part overlapping with each other, and the overlapping part of the two gate metal frames 12 is defined as an overlapping line (overlapping line A1 or overlapping line A2, please refer to FIG. 4).

In some embodiments of the present invention, if two adjacent gate metal frames 12 are adjacent to each other in the X direction, the overlapping line A1 extends in the Y direction.

In some embodiments of the present invention, if two adjacent gate metal frames 12 are adjacent to each other in the Y direction, the overlapping line A2 extends in the X direction.

In some embodiments of the present invention, the plurality of gate patterns 14 and the gate metal frame 12 are electrically connected to a common gate pad 26.

In some embodiments of the present invention, a plurality of gate metal frames 12 are arranged in an array.

In some embodiments of the present invention, the common gate pad 26 is located beside the array arranged by the gate metal frames 12.

In some embodiments of the present invention, a plurality of source/drain contacts 20 are further included to electrically connect a plurality of source/drain patterns 16.

In some embodiments of the present invention, when viewed from a top view, a plurality of source/drain contacts 20 overlap with a portion of the gate metal frame 12.

In some embodiments of the present invention, a source/drain circuit layer 22 is further included, which is electrically connected with the plurality of source/drain contacts 20.

In some embodiments of the present invention, the source/drain circuit layer 22 and part of the source/drain pattern 16 overlap each other when viewed from the top view.

The invention also provides a semiconductor stacking structure, which comprises a substrate Sub, a first chip 300A and a second chip 300B are stacked on the substrate Sub, wherein the first chip 300A and the second chip 300B respectively comprise a first power amplifier MCS and a second power amplifier MCG. The first power amplifier MCS and the second power amplifier MCG each include a source terminal S, a drain terminal D and a gate terminal G, and the drain terminal D of the first power amplifier MCS is electrically connected with the source terminal S of the second power amplifier MCG, and the first power amplifier MCS and the second power amplifier MCG are stacked to form a cascade power amplifier.

In some embodiments of the present invention, when viewed from a top view, the first chip 300A or the second chip 300B each includes a plurality of gate metal frames 12 arranged on the substrate Sub, wherein each gate metal frame 12 includes a plurality of source/drain patterns 16 and a plurality of gate patterns 14 extending along an X direction, and the plurality of source/drain patterns 16 and the plurality of gate patterns 14 are alternately arranged along a Y direction, a part of any two adjacent gate metal frames 12 overlap each other.

In some embodiments of the present invention, the first chip 300A or the second chip 300B each includes a plurality of source/drain contacts 20, which are electrically connected to a part of the source/drain pattern 16. And a source/drain circuit layer 22 is included, which is electrically connected to the source/drain contacts 20 and connected to the source terminal S or the drain terminal D, wherein when viewed from the top view, the plurality of source/drain contacts 20 overlap with part of the metal gate frame 12.

In some embodiments of the present invention, the gate terminal G of the first power amplifier MCS of the first chip 300A is connected to an input signal RFin, and the source terminal S of the first power amplifier MCS is grounded (connected to the ground potential GND).

In some embodiments of the present invention, the gate terminal G of the second power amplifier MCG of the second chip 300B is connected to a voltage source Vcas, and the drain terminal D of the second power amplifier MCG is connected to an output signal RFout.

In some embodiments of the present invention, the drain terminal D of the first power amplifier MCS and the source terminal S of the second power amplifier MCG are electrically connected through a hybrid bond (HB).

In some embodiments of the present invention, a heat sink 34 is further included, which is located on the back of the second power amplifier MCG of the second chip 300B.

The invention is characterized by providing a semiconductor layout pattern suitable for composing a power amplifier, and a power amplifier formed by stacking the semiconductor layout patterns mentioned above. Each power amplifier layout pattern comprises a plurality of gate metal frames, and each gate metal frame is arranged next to each other, that is to say, there is no gap between the gate metal frames, and the subsequent contact structures or wires partially overlap the gate metal frames. In this way, the gate metal frames can be arranged more closely with each other, and the area of the overall semiconductor layout pattern can be reduced. According to the experimental results of the applicant, when the improved semiconductor layout pattern provided by the invention is applied to a power amplifier, the efficiency of the power amplifier can also be effectively improved. Besides, the invention also provides a cascade power amplifier structure formed by stacking two semiconductor layout patterns, and the cascade power amplifier formed by the invention has better efficiency and smaller area.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor layout pattern, comprising:
a substrate;
a plurality of gate metal frames arranged on the substrate, wherein each gate metal frame comprises:
a plurality of source/drain patterns and a plurality of gate patterns extend along an X direction, and the plurality of source/drain patterns and the plurality of gate patterns are alternately arranged along a Y direction; and
wherein, any two adjacent gate metal frames have a part overlapping with each other, and the overlapping part of the two gate metal frames is defined as an overlapping line.

2. The semiconductor layout pattern according to claim 1, wherein if the two adjacent gate metal frames are adjacent to each other in the X direction, the overlapping line extends in the Y direction.

3. The semiconductor layout pattern according to claim 1, wherein if the two adjacent gate metal frames are adjacent to each other in the Y direction, the overlapping line extends in the X direction.

4. The semiconductor layout pattern according to claim 1, wherein the plurality of gate patterns and the gate metal frame are electrically connected to a common gate pad.

5. The semiconductor layout pattern according to claim 4, wherein the plurality of gate metal frames are arranged in an array.

6. The semiconductor layout pattern according to claim 5, wherein the common gate pad is located beside the array arranged by the gate metal frames.

7. The semiconductor layout pattern according to claim 1, further comprising a plurality of source/drain contacts electrically connecting the plurality of source/drain patterns.

8. The semiconductor layout pattern according to claim 7, wherein the plurality of source/drain contacts overlap with a part of the gate metal frame when viewed from a top view.

9. The semiconductor layout pattern according to claim 8, further comprising a source/drain circuit layer electrically connected to the plurality of source/drain contacts.

10. The semiconductor layout pattern according to claim 9, wherein the source/drain circuit layer and part of the gate metal frame overlap each other when viewed from a top view.

11. A semiconductor stacked structure, comprising:
a substrate;
a first chip and a second chip stacked on the substrate, wherein the first chip and the second chip respectively comprise a first power amplifier and a second power amplifier, and the first power amplifier and the second power amplifier respectively comprise a source terminal, a drain terminal and a gate terminal, and the drain terminal of the first power amplifier is electrically connected with the source terminal of the second power amplifier, and the first power amplifier and the second power amplifier are stacked to form a cascade power amplifier.

12. The semiconductor stacked structure according to claim 11, wherein the first power amplifier or the second power amplifier respectively comprises:
a plurality of gate metal frames arranged on the substrate, wherein each gate metal frame comprises a plurality of source/drain patterns and a plurality of gate patterns extending along an X direction, and the plurality of source/drain patterns and the plurality of gate patterns are alternately arranged along a Y direction, wherein a part of any two adjacent gate metal frames overlap each other.

13. The semiconductor stacked structure according to claim 12, wherein the first chip or the second chip respectively comprises:
a plurality of source/drain contacts electrically connecting a part of the source/drain patterns;
a source/drain circuit layer electrically connected to the plurality of source/drain contacts and connected to the source terminal or the drain terminal;
wherein when viewed from the top view, the plurality of source/drain contacts overlap with part of the metal gate frame.

14. The semiconductor stacked structure according to claim 11, wherein the gate terminal of the first power amplifier of the first chip is connected to an input signal, and the source terminal of the first power amplifier is grounded.

15. The semiconductor stacked structure according to claim 11, wherein the gate terminal of the second power amplifier of the second chip is connected to a voltage source, and the drain terminal of the second power amplifier is connected to an output signal.

16. The semiconductor stacked structure according to claim 11, wherein the drain terminal of the first power amplifier and the source terminal of the second power amplifier are electrically connected through a hybrid bond.

17. The semiconductor stacked structure according to claim 11, further comprising a heat sink located on the back of the second power amplifier of the second chip.
